(19) United States
(12) Patent Application Publication
(10) Pub. No.: US 2024/0060179 A1
(43) Pub. Date: Feb. 22, 2024

(54) ATOMIC LAYER DEPOSITION DEVICE AND ATOMIC LAYER DEPOSITION METHOD

(71) Applicant: MEIDEN NANOPROCESS INNOVATIONS, INC., Shinagawa-ku, Tokyo (JP)

(72) Inventors: Naoto KAMEDA, Moriya-shi, Ibaraki (JP); Takayuki HAGIWARA, Nagareyama-shi, Chiba (JP); Ayaka ABE, Yachiyo-shi, Chiba (JP); Tatsunori SHINO, Chiba-shi, Chiba (JP); Soichiro MOTODA, Chiba-shi, Chiba (JP)

(21) Appl. No.: 18/039,695

(22) PCT Filed: Dec. 1, 2021
(86) PCT No.: PCT/JP2021/044076

§ 371 Date: May 31, 2023

(30) Foreign Application Priority Data
Dec. 1, 2020 (JP) 2020-199543
Aug. 24, 2021 (JP) 2021-135997

(51) Int. Cl. C23C 16/455; C23C 16/52; C23C 16/40

(52) U.S. Cl. CPC C23C 16/45527; C23C 16/52; C23C 16/45544; C23C 16/40

(57) ABSTRACT

Provided is an atomic layer deposition device with a gas supply system for supplying respective gases into a chamber in which a target workpiece is removably disposed. The gas supply system includes a raw material gas supply line that supplies a raw material gas into the chamber; an ozone gas supply line that supplies an ozone gas of 80 vol % or higher into the chamber; and an inert gas supply line that supplies an inert gas into the chamber. The ozone gas supply line has an ozone gas buffer part that freely accumulates and seals therein the ozone gas in the ozone gas supply line and freely feeds the accumulated ozone gas into the chamber by opening and closing of an open/close valve mounted on the ozone gas supply line, and an ozone gas buffer part pressure gauge that measures a gas pressure inside the ozone gas buffer part.

### FIELD OF THE INVENTION

The present invention relates an atomic layer deposition device and an atomic layer deposition method as a technique of forming a thin film applicable to semiconductor devices and the like.

### BACKGROUND ART

As typical techniques of forming thin films (hereinafter occasionally simply referred to as film formation) for advanced devices such as semiconductor devices (e.g. CPU circuits), there are known vapor deposition, sputtering, chemical vapor deposition (CVD) and atomic layer deposition (ALD). Among others, ALD is superior in terms of step coverage property and film density and has become an essential thin film forming technique for advanced devices (see, for example, Patent Document 1).

In general, an ALD process is performed by repeating the following four steps: entirely evacuating a chamber (such as vacuum vessel) in which a target workpiece (e.g. a silicon wafer) is disposed; supplying a raw material gas (e.g. TMA (trimethyl aluminum)) for ALD into the chamber; removing the raw material gas from the chamber; and supplying into the chamber an oxidant (e.g. water vapor) for oxidation of the raw material gas. By supplying the raw material gas into the chamber and filling the inside of the chamber with the raw material gas, the raw material gas is adsorbed in an amount of one molecular layer onto a surface (called a film formation surface) of the target workpiece so that a molecular layer of the raw material gas is formed on the film formation surface of the target workpiece.

By subsequently supplying the oxidant of the raw material gas into the chamber, the molecular layer of the raw material gas formed on the film formation surface is oxidized so that a thin-film molecular layer of an oxide of the raw material gas (e.g. a thin film of aluminum oxide) is formed on the film formation surface. When the above-mentioned four-step process is repeatedly performed, the thin film layer is provided with a film thickness according to the number of repetitions of the four-step process.

In ALD film forming processes, the film forming temperature tends to become high. For instance, the target workpiece needs to be heated to a relatively high temperature (e.g. 300° C. to 500° C.) in order to cause sufficient reaction of TMA and water vapor. In the case of a compound semiconductor material such as GAN or ZnO used for advanced devices, a plurality of semiconductor thin film layers of slightly different compositions might be stacked on the film formation surface of the target workpiece due to heteroepitaxy or MBE (molecular beam epitaxy) during the film forming process. Since these semiconductor thin film layers are susceptible to compositional deviations by heating, it is strongly demanded to perform the film formation process at a low temperature.

For other advanced devices, there is an idea that that the film forming temperature of ALD processes is preferably in the range of room temperature to 100° C. Thus, studies are being made on ALD processes using ozone (O₃) or plasma oxygen as an oxidant and causing reaction by the action of radials generated from the oxidant. The use of ozone leads to a reduction of film forming temperature because O₃ radicals can be generated as strong oxidant species by thermal decomposition of ozone. Even in the film forming process using ozone, however, it is still necessary to heat the target workpiece to several hundreds ° C. The use of plasma oxygen enables supply of O radicals from the beginning whereby the most reduction of film forming temperature can be expected. Even in the film forming process using plasma ozone, however, the film forming temperature is reduced to only about 100° C. to 150° C. Hence, a further reduction of film forming temperature is desired for atomic layer deposition processes.

Furthermore, the film forming efficiency tends to become low because of long film forming time etc. in conventional ALD film forming processes. In order to form one molecular layer of the raw material gas by ALD on the film formation surface, it is necessary to first allow adsorption of the raw material gas onto the film formation surface, remove the residual raw material gas, and then, oxidize the raw material gas layer (adsorption layer) formed on the film formation surface. In general, it takes several minutes to carry out these process steps. In the case of aluminum oxide, for example, one molecular layer is about 0.1 nm in thickness. For the formation of a practical aluminum oxide film with a thickness of the order of 10 nm, about 100 molecular layers of aluminum oxide are required. Assuming the time required to form one molecular layer of aluminum oxide as 30 seconds, it takes about 50 minutes to form such a practical aluminum oxide film by atomic layer deposition. By contrast, it is possible by the other film forming processes such as CVD to form films of about 10 nm thickness within 1 minute. The film forming time of the ALD processes, which is longer than that of the other film formation processes, could become a big disadvantage.

In recent years, studies are also being made on other film forming techniques such as a technique of forming a film by single wafer processing with the supply of respective gases such as raw material gas and oxidant gas through a shower head and a technique of forming a film with the use of OH radicals generated by reaction of ozone and unsaturated hydrocarbon as oxidant species (see, for example, Patent Documents 2 and 3).

### PRIOR ART DOCUMENTS

### Patent Documents

Patent Document 1: Japanese Laid-Open Patent Publication No. 2004-057014
Patent Document 2: Japanese Patent No. 6702514
Patent Document 3: Japanese Patent No. 6677356

### Non-Patent Documents

Non-Patent Document 1: News Release 2018, “Meiden Developed Groundbreaking Technology for Atomic Layer Deposition at Room Temperature” (online), Jul. 31, 2019, Meidensha Corporation Homepage, Internet, http://www.meidensha.co.jp/news/news_03/news_03_01/1227605_2469.html>

### SUMMARY OF THE INVENTION

Radicals used for common ALD processes are relatively short in lifetime and thus are difficult to diffuse widely in the chamber. It may be difficult for such radicals to oxidize the raw material gas adsorbed on the film formation surface of e.g. uneven shape.

Therefore, there arise tendencies that: the target workpiece is limited to a plate-shaped substrate with a flat film formation surface; the ALD process is limited to single wafer processing; and it becomes difficult to form the film with desired quality.

In view of the above-mentioned tendencies, improvements of film forming efficiency and film forming accuracy (such as shortening of film forming time and quality improvement of oxide film) are demanded.

The present invention has been made under the foregoing circumstances. It is an object of the present invention to provide a technique which contributes to improvements of film forming efficiency and film forming accuracy (such as shortening of film forming time and quality improvement of oxide film).

An atomic layer deposition device and an atomic layer deposition method according to the present invention are provided as a solution to the above-mentioned object.

More specifically, one aspect of the present invention is an atomic layer deposition device comprising: a chamber in which a target workpiece is removably disposed; a gas supply system that provides a supply of gas into the chamber; and a gas discharge system that discharges any gas inside the chamber by suction to the outside of the chamber and maintains the inside of the chamber in a reduced pressure state, wherein the gas supply system comprises: a raw material gas supply line having a raw material gas supply pipe for supplying a raw material gas into the chamber; an ozone gas supply line having an ozone gas supply pipe for supplying an ozone gas of 80 vol % or higher into the chamber; and an inert gas supply line having an inert gas supply pipe for supplying an inert gas into the chamber, and wherein the ozone gas supply line comprises: an ozone gas buffer part that freely accumulates and seals therein the ozone gas flowing in the ozone gas supply pipe and freely feeds the accumulated ozone gas into the chamber by opening and closing of an open/close valve mounted on the ozone gas supply pipe; and an ozone gas buffer part pressure gauge that measures a gas pressure inside the ozone gas buffer part.

The atomic layer deposition device may further comprise an ozone gas accumulation amount control part that controls the amount of accumulation of the ozone gas in the ozone gas buffer part based on a change in measured value of the ozone gas buffer part pressure gauge.

The volume inside the ozone gas buffer part may be larger than or equal to 1/50 of the volume inside the chamber.

The volume inside a part of the ozone gas supply pipe downstream of the ozone gas buffer part may be in the range of 1/10 to ½ of the volume inside the ozone gas buffer part.

The ozone gas supply pipe may have an ozone gas nozzle portion formed on a downstream end part thereof and arranged to protrude from an inner surface of the chamber; whereas the raw material gas supply pipe may have a raw material gas nozzle portion formed on a downstream end part thereof and arranged to protrude from the inner surface of the chamber. Each of the ozone gas nozzle portion and the raw material gas nozzle portion may include: a cylindrical section protruding from the inner surface of the chamber; a lid section closing a front end of the cylindrical section in a protruding direction of the cylindrical section; and a plurality of nozzle holes opening through an outer cylindrical surface of the cylindrical section in a radial direction of the cylindrical section.

The ozone gas nozzle portion and the raw material gas nozzle portion may protrude from the inner surface of the chamber in parallel with each other such that the nozzle holes of the ozone gas nozzle portion and the nozzle holes of the raw material gas nozzle portion are positioned opposed to and facing each other.

The atomic layer deposition device may comprise a chamber inside heating part arranged in a space between the ozone gas nozzle portion and the raw material gas nozzle portion within the chamber to heat the space between the ozone gas nozzle portion and the raw material gas nozzle portion as heating means capable of heating the space between the ozone gas nozzle portion and the raw material gas nozzle portion to a higher temperature than a temperature inside the ozone gas supply pipe and a temperature inside the raw material gas supply pipe.

The atomic layer deposition device may comprise an inner surface temperature adjusting part arranged to adjust a temperature of the inner surface of the chamber as heating means capable of adjusting the temperature of the inner surface of the chamber to a higher temperature than a temperature inside the ozone gas supply pipe and a temperature inside the raw material gas supply pipe. In this configuration, the ozone gas nozzle portion and the raw material gas nozzle portion may protrude from the inner surface of the chamber in parallel with each other such that the nozzle holes of the ozone gas nozzle portion and the nozzle holes of the raw material gas nozzle portion are oriented in opposite directions and facing away from each other.

Further, the chamber may have a gas flow guide portion provided protrudingly from the inner surface of the chamber such that the gas flow guide portion extends from the inner surface of the chamber toward a position of the target workpiece in the chamber.

The gas supply system may comprise a plurality of the raw material gas supply lines arranged in parallel to the chamber.

The atomic layer deposition device may further comprise a supply pipe temperature adjusting part capable of adjusting temperatures inside the respective raw material gas supply pipes of the raw material gas supply lines.

The raw material gas supply line may comprise: a raw material gas buffer part that freely accumulates and seals therein the raw material gas flowing in the raw material gas supply pipe and freely feeds the accumulated raw material gas into the chamber by opening and closing of an open/close valve mounted on the raw material gas supply pipe; and a raw material gas buffer part pressure gauge that measures a gas pressure inside the raw material gas buffer part.

The atomic layer deposition device may further comprise a raw material gas accumulation amount control part that controls the amount of accumulation of the raw material gas in the raw material gas buffer part based on a change in measured value of the raw material gas buffer part pressure gauge.

The volume inside the raw material gas buffer part may be larger than or equal to 1/500 of the volume inside the chamber.

The volume inside a part of the raw material gas supply pipe downstream of the raw material gas buffer part may be in the range of 1/10 to ½ of the volume inside the raw material gas buffer part.

The raw material gas supply line may comprise a bypass line provided on a side of the raw material gas supply pipe upstream and/or downstream of the raw material gas buffer part and having a bypass pipe switchable between a communication state and a shut-off state to establish or shut off communication between the raw material gas buffer part and the gas discharge system.

Furthermore, the raw material gas supply line may comprise an inert gas addition line having an inert gas addition pipe switchable between a communication state and a shut-off state to establish or shut off communication between the raw material gas supply pipe and the inert gas supply pipe.

The atomic layer deposition device may be structured such that: the raw material gas supply line comprises an inert gas addition line having an inert gas addition pipe switchable between a communication state and a shut-off state to establish or shut off communication between the raw material gas supply pipe and the inert gas supply pipe; and the raw material gas buffer part is configured to, by opening and closing of the open/close valve mounted on the raw material gas supply pipe, freely accumulate and seal therein a mixed gas of the raw material gas flowing in the raw material gas supply pipe and the inert gas flowing from the inert gas supply pipe into the raw material gas supply pipe via the inert gas addition line and freely feed the accumulated mixed gas into the chamber.

The atomic layer deposition device may comprise an addition pipe temperature adjusting part capable of adjusting a temperature inside the inert gas addition pipe to a higher temperature than a temperature inside the raw material gas supply pipe.

Another aspect of the present invention is an atomic layer deposition method using the above-mentioned atomic layer deposition device for forming an oxide film on a film formation surface of a target workpiece disposed in the chamber of the atomic layer deposition device, the atomic layer deposition method comprising: a raw material gas supply step of supplying a raw material gas, which contains a constituent element of the oxide film, into the chamber, thereby forming an adsorption layer of the raw material gas on the film formation surface; a raw material gas purge step of removing, from the film formation surface, a residue of the raw material gas supplied in the raw material gas supply step and any gas generated by adsorption of the raw material gas on the film formation surface; an oxidant supply step of supplying an ozone gas of 80 vol % or higher into the chamber, thereby oxidizing the adsorption layer formed on the film formation surface; and an oxidant purge step of removing, from the film formation surface, a residue of the ozone gas supplied in the oxidant supply step and any gas generated by oxidation of the adsorption layer.

Still another aspect of the present invention is an atomic layer deposition method using the above-mentioned atomic layer deposition device for forming an oxide film on a film formation surface of a target workpiece disposed in the chamber of the atomic layer deposition device, the atomic layer deposition method comprising: a raw material gas supply step of supplying a mixed gas of a raw material gas, which contains a constituent element of the oxide film, and an inert gas into the chamber, thereby forming an adsorption layer of the raw material gas on the film formation surface; a raw material gas purge step of removing, from the film formation surface, a residue of the raw material gas of the mixed gas supplied in the raw material gas supply step and a gas generated by adsorption of the raw material gas of the mixed gas onto the film formation surface; an oxidant supply step of supplying an ozone gas of 80 vol % or higher into the chamber, thereby oxidizing the adsorption layer formed on the film formation surface; and an oxidant purge step of removing, from the film formation surface, a residue of the ozone gas supplied in the oxidant supply step and a gas generated by oxidation of the adsorption layer, wherein the mixed gas supplied in the raw material gas supply step is prepared in advance by the execution of: a raw material gas accumulation step of accumulating the raw material gas in the raw material gas buffer part until a pressure inside the raw material gas buffer part reaches a predetermined pressure; and then, a mixed gas accumulation step of obtaining and accumulating the mixed gas in the raw material gas buffer part by supplying an inert gas into the raw material gas buffer part via the inert gas addition pipe until the pressure inside the raw material gas buffer part reaches a predetermined pressure higher than that in the raw material gas accumulation step.

The raw material gas accumulation step may be performed in such a manner that the partial pressure of the raw material gas in the mixed gas accumulated in the raw material gas buffer part is 1000 Pα or lower; and the concentration of the raw material gas in the mixed gas is 30% or lower as a converted value based on a partial pressure ratio of the raw material gas and the inert gas in the mixed gas.

The raw material gas supply step may be performed in such a manner that: the supply of the mixed gas accumulated in the raw material gas buffer part to the chamber is completed within 1 second: and the pressure inside the chamber is in the range of 0.1 to 100 Pα.

The atomic layer deposition method may comprise, after the raw material gas supply step, feeding an inert gas into the raw material gas supply pipe so as to replace any residual gas inside the raw material gas supply pipe with the inert gas.

The oxidant supply step may be performed in such a manner that the partial pressure of the ozone gas accumulated in the ozone gas buffer part is 10000 Pα or lower.

The oxidant supply step may be performed in such a manner that: the supply of the ozone gas accumulated in the ozone gas buffer part to the chamber is completed within 1 second; and the pressure inside the chamber is in the range of 10 to 1000 Pα.

In the atomic layer deposition method, the gas supplied into the chamber in the raw material gas supply step may be kept sealed in the chamber for a predetermined time, and then, discharged to the outside of the chamber in the raw material gas purge step; and the gas supplied into the chamber in the oxidant supply step may be kept sealed in the chamber for a predetermined time, and then, discharged to the outside of the chamber in the oxidant purge step.

Each of the raw material gas purge step and the oxidant purge step may be performed by supplying the inert gas repeatedly a plurality of times in such a manner that the amount of the inert gas supplied repeatedly is 10 times or more than the amount of the gas supplied into the chamber in the raw material gas supply step or is 10 times or more than the amount of the gas supplied into the chamber in the oxidant supply step.

In the atomic layer deposition method, each of the time during which the gas supplied in the raw material gas supply step is kept sealed in the chamber and the time during which the gas supplied in the oxidant supply step is kept sealed in the chamber may be in the range of 1 to 1000 seconds.

The atomic layer deposition method may be carried out by performing a plurality of cycles of the raw material gas supply step, the raw material gas purge step, the oxidant supply step and the oxidant purge step in such a manner that the raw material gas supplied in the raw material gas supply step of at least one of the plurality of cycles is of different kind from the raw material gas supplied in the raw material gas supply step of the other of the plurality of cycles.

Furthermore, the oxide film may include an adsorption layer of any of Al₂O₃, HfO₂, TiO₂, ZnO, Ta₂O₃, Ga₂O₃, MoO₃, RuO₂, SiO₂, ZrO₂ and Y₂O₃.

The above-described present invention contributes to improvements of film forming efficiency and film forming accuracy.

### BRIEF DESCRIPTION OF DRAWINGS

FIG. 1 is a schematic configuration diagram of an ALD device according to one embodiment of the present invention.

FIG. 2 is a schematic cross-sectional view of an example of a target workpiece 2.

FIG. 3 is a flowchart for formation of an oxide film 21.

FIGS. 4(a) and 4(b) depict a reaction scheme of an example of formation of an oxide film 21.

FIG. 5 is a characteristic diagram of changes in pressure with time for explaining an example of a film forming cycle of process steps S1 to S4.

FIG. 6 is a cross-sectional image for explaining results of cross-sectional observation during formation of an oxide film 21 in Embodiment Example 3.

FIG. 7 is a schematic configuration diagram of a gas nozzle portion 61, 62 of a pipe L11, L21 in Embodiment Example 4 (more specifically, a cross-sectional view of a cylindrical section 6a of the gas nozzle portion as taken in an axial direction and as seen from an inner side of the cylindrical section 6a).

FIG. 8 is a schematic view of an arrangement configuration of gas nozzle portions 61 and 62 of pipes L11 and L21 in Embodiment Example 4 (where (A) illustrates the inside of the chamber 3 as viewed from an opening end 22a side of the target workpiece 2 (with illustration of the opening end 22a omitted herefrom); and (B) illustrates the inside of the chamber 3 from a lid section 6b side of the nozzle portion (with cross section of the target workpiece 2 taken in the same manner as in FIG. 2)).

FIG. 9 is a schematic view of a gas heating configuration inside the chamber 3 in Embodiment Example 5 (where the illustrations (A) and (B) are drawn in the same manner as in FIG. 8).

FIG. 10 is a schematic view of a gas heating configuration inside the chamber 3 in Embodiment Example 6 (where the illustrations (A) and (B) are drawn in the same manner as in FIG. 8).

### DESCRIPTION OF EMBODIMENTS

An atomic layer deposition device and atomic layer deposition method according to an exemplary embodiment of the present invention (hereinafter occasionally referred to as ALD device and ALD method, respectively) are totally different from conventional ALD methods adopting relatively high film forming temperatures and using radicals generated from oxidants (hereinafter occasionally simply referred to as conventional ALD methods).

More specifically, the present embodiment refers to an ALD device and an ALD method using the same, wherein the ALD device comprises: a chamber in which a target workpiece is removably disposed; a gas supply system that supplies respective gases into the chamber; and a gas discharge system that discharges any gas inside the chamber by suction to the outside of the chamber and maintains the inside of the chamber in a reduced pressure state. The gas supply system includes: a raw material gas supply line having a raw material gas supply pipe for supplying a raw material gas into the chamber; an ozone gas supply line having an ozone gas supply pipe for supplying an ozone gas of 80 vol % or higher into the chamber; and an inert gas supply line having an inert gas supply pipe for supplying an inert gas into the chamber.

The ozone gas supply line has: an ozone gas buffer part that freely accumulates and seals therein the ozone gas flowing in the ozone gas supply pipe and freely feeds the accumulated ozone gas into the chamber by opening and closing of an open/close valve mounted on the ozone gas supply pipe; and an ozone gas buffer part pressure gauge that measures a gas pressure inside the ozone gas buffer part.

The above-configured device configuration of the present embodiment makes it easy to diffuse the ozone gas widely in the chamber so that the raw material gas adsorbed on e.g. an uneven film formation surface of the target workpiece can be sufficiently oxidized by the ozone gas.

Thus, the present embodiment enables sufficient oxidation of the raw material gas adsorbed on the film formation surface of the target workpiece, without heating the target workpiece and without using radicals as oxidant species, so as to thereby form an oxide film of desired quality. Further, it is possible to dispose a plurality of target workpieces in the chamber and form oxide films on respective film formation surfaces of the target workpieces in one operation (e.g. by batch processing using a chamber of relatively large volume). These features lead to improvements of film forming efficiency and film forming accuracy.

Since the high concentration ozone gas of 80 vol % or higher is supplied, the oxide film can be formed even at a relatively low temperature (e.g. 100° C. or lower). Hence, the oxide film is appropriately applicable to not only relatively high heat-resistant substrates such as S1 substrate but also substrates or films made of relatively low heat-resistant synthetic resins.

The ALD device and the ALD method can be embodied in various forms as long as the gas supply system is provided with the raw material gas supply line, the ozone gas supply line and the inert gas supply line; and the ozone gas buffer part of the ozone gas supply line is capable of temporarily and freely accumulating and sealing therein the ozone gas and freely feeding the accumulated ozone gas into the chamber. It is feasible to modify the design of the atomic layer deposition device and method by appropriately applying the common general technical knowledge of various fields (such as the field of film formation by ALD, CVD etc., the field of chambers, the field of ozone gases, the field of gas supply lines and the like). The following are examples of the present embodiment.

It is herein noted that, in the following embodiment examples, like parts and portions are designated by the same reference numerals to omit a detailed description thereof.

### Embodiment

<Main Configuration of ALD Device 11>

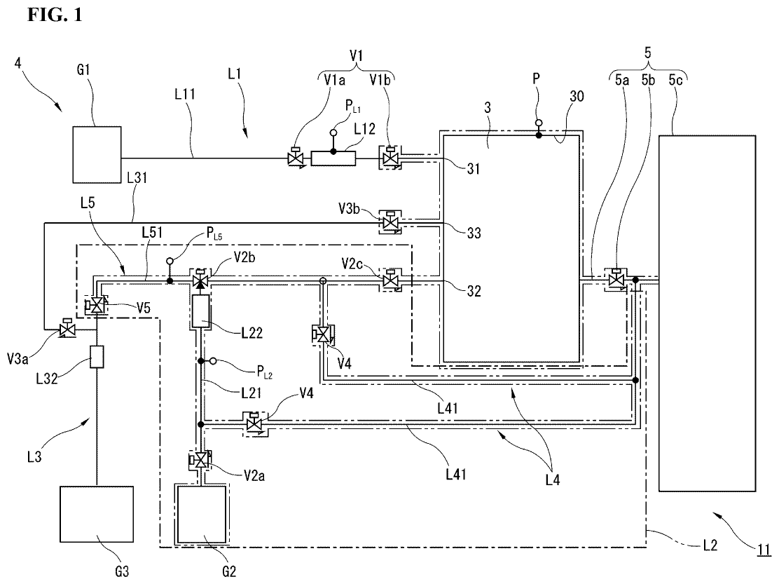

FIG. 1 schematically shows the configuration of an ALD device 11 according to one embodiment of the present invention.

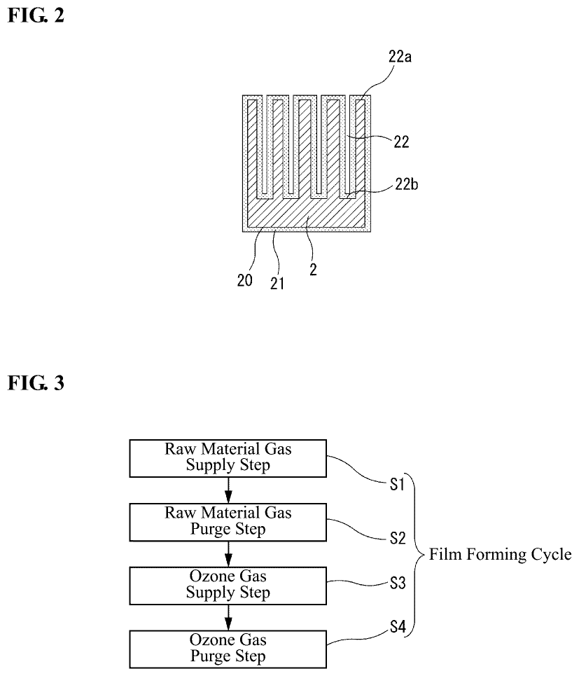

The ALD device 11 generally includes: a chamber (reaction container) 3 in which a target workpiece 2 as explained later with reference to FIG. 2 is removably disposed; a gas supply system 4 that supplies respective gases into the chamber 3; and a gas discharge system 5 that discharges any gas inside the chamber 3 by suction to the outside of the chamber 3. The target workpiece 2 disposed in the chamber 3 is properly supported by a support part (not shown).

The chamber 3 has: an ozone gas ejection port 31 through which an ozone gas is ejected into the chamber 3; a raw material gas ejection port 32 through which a raw material gas is ejected into the chamber 3; and an inert gas ejection port 33 through which an inert gas is ejected into the chamber 3. These ejection ports 31 to 33 are provided at positions opposed to and facing the target workpiece 2 in the chamber 3 (in FIG. 1, at positions on the upper side of the chamber 3). A pressure gauge P is arranged on the chamber 3 so as to measure a gas pressure inside the chamber 3.

The gas supply system 4 has: an ozone gas supply line L1 that supplies an ozone gas (such as an ozone gas of 80 vol % or higher) generated by an ozone gas generator G1 into the chamber 3 through the ozone gas ejection port 31; a raw material gas supply line L2 that supplies a raw material gas fed from a raw material gas supply device G2 into the chamber 3 through the raw material gas ejection port 32; and an inert gas supply line L3 that supplies an inert gas fed from an inert gas supply device G3 into the chamber 3 through the inert gas ejection port 33.

The gas discharge system 5 is arranged at a position apart from the respective ejection ports 31 to 33 of the chamber 3 (in FIG. 1, at a position on the lateral side of the chamber 3). The gas discharge system 5 is configured to discharge any gas inside the chamber 3 by suction to the outside of the chamber 3 and maintain the inside of the chamber 3 in a reduced pressure state (e.g. maintain the inside of the chamber 3 under vacuum). In the present embodiment, the gas discharge system 5 has a discharge pipe 5a, an open/close valve 5b and a vacuum pump 5c as shown in FIG. 1.

Ozone Gas Supply Line L1

The ozone gas supply line L1 provides a connection between the ozone gas generator G1 and the ejection port 31, and has an ozone gas supply pipe L11 for supplying an ozone gas generated by and fed from the ozone gas generator G1. The pipe L11 is equipped with ozone gas on/off valves V1 and an ozone gas buffer part L12. Each of the on/off valves V1 is switchable between a gas flow state (open state) and a gas cut-off state (closed state) to allow or cut off gas flow in the pipe L11. (in FIG. 1, the on/off valves V1a and V1b are disposed on upstream and downstream sides of the ozone gas buffer part L12). The ozone gas buffer part L12 is configured to freely accumulate and seal therein the ozone gas in the pipe L11 (more specifically, the ozone gas on the upstream side of the chamber 3) and freely feed the accumulated ozone gas into the chamber 3 by opening and closing of the on/off valves V1. Further, an ozone gas buffer part pressure gauge P_{L1} is provided on the pipe L11 to measure a gas pressure inside the ozone gas buffer part L12.

There is no particular limitation on the form of the ozone gas buffer part L12. The ozone gas buffer part L12 can be in any form as long as it is capable of freely accumulating and sealing therein the ozone gas flowing in the pipe L11 at a predetermined pressure and freely feeding the accumulated ozone gas to the chamber 3 at the predetermined pressure. In one embodiment example, the inside volume of the ozone gas buffer part L12 is set larger than or equal to about 1/50 of the inside volume of the chamber 3 (for instance, the inside volume of the ozone gas buffer part L12 is set to 1000 cc when the inside volume of the chamber 3 is set to 50000 cc) so that the gas pressure inside the ozone gas buffer part L12 can be maintained at about 10000 Pα or lower.

Further, the inside volume of a part of the pipe L11 downstream of the ozone gas buffer part L12 (in FIG. 1, the inside volume of a part of the pipe L11 extending from the outlet of the ozone gas buffer part L12 to the ejection port 31 and, in the case where an ozone gas nozzle portion 61 is provided as explained later, including the ozone gas nozzle portion 61) is set as appropriate. In one embodiment example, the inside volume of the part of the pipe L11 downstream of the ozone gas buffer part L12 is set to within the range of 1/10 to ½ of the inside volume of the ozone gas buffer part 12.

It is feasible to control the amount of accumulation of the ozone gas in the ozone gas buffer part L12 (that is, the amount of feeding and supply of the ozone gas into the chamber 3) by e.g. an ozone gas accumulation amount control part based on a change in the measured value of the pressure gauge P_{L1}.

Various forms of open/close valves are usable as the on/off valves V1. In one embodiment example, the on/off valves V1a and V1b are provided on upstream and downstream sides of the ozone gas buffer part L12, respectively, as shown in FIG. 1. Automatic valves can be used as the on/off valves V1a and V1b.

As explained above, the ozone gas supply line L1 is adapted to, by appropriately opening and closing the on/off valves V1 and adequately controlling the gas pressure inside the ozone gas buffer part L12 based on the change in the measured value of the pressure gauge PU, accumulate therein the ozone gas at a predetermined pressure and concentration and supply the accumulated ozone gas into the chamber 3.

Any residual ozone gas remaining in the ozone gas buffer part L12 after the supply of the ozone gas into the chamber 3 may be accumulated and used along with an ozone gas newly fed from the ozone gas generator G1 (i.e. recycled for supply to the chamber 3) in the next ozone gas accumulation.

<Raw Material Gas Supply Line L2>

The raw material gas supply line L2 provides a connection between the raw material gas supply device G2 and the ejection port 32, and has a raw material gas supply pipe L21 for supplying a raw material gas fed from the raw material gas supply device G2. The pipe L21 is equipped with raw material gas on/off valves V2 and a raw material gas buffer part L22. Each of the on/off valves V2 is switchable between a gas flow state (open state) and a gas cut-off state (closed state) to allow or cut off gas flow in the pipe L21. (In FIG. 1, the on/off valves V2a to V2c are disposed on upstream and downstream sides of the raw material gas buffer part L22). The raw material gas buffer part L22 is configured to freely accumulate and seal therein the ozone gas in the pipe L21 (more specifically, the ozone gas on the upstream side of the chamber 3) and freely feed the accumulated raw material gas into the chamber 3 by opening and closing of the on/off valves V2.

Further, a raw material gas buffer part pressure gauge P_{L2} is provided on the pipe L21 to measure a gas pressure inside the raw material gas buffer part L22. In the embodiment of FIG. 1, a bypass line L4 and an inert gas addition line L5 are provided to the pipe L21 as will be explained later.

There is no particular limitation on the form of the raw material gas buffer part L22. The raw material gas buffer part L12 can be in any form it is capable of freely accumulating and sealing therein the raw material gas flowing in the pipe L21 at a predetermined pressure and freely feeding the accumulated raw material gas to the chamber 3 as appropriate at the predetermined pressure. In one embodiment example, the inside volume of the raw material gas buffer part L22 is set larger than or equal to about 1/500 of the internal volume of the chamber 3 (for instance, the inside volume of the raw material gas buffer part L22 is set to 100 cc when the inside volume of the chamber 3 is set to 50000 cc) so that the gas pressure inside the raw material gas buffer part L22 can be maintained at about 100000 Pα or lower.

Further, the inside volume of a part of the pipe L21 downstream of the raw material gas buffer part L22 (in FIG. 1, the inside volume of a part of the pipe L21 extending from the outlet of the raw material gas buffer part L22 to the ejection port 32 and, in the case where a raw material gas nozzle portion 62 is provided as explained later, including the raw material gas nozzle portion 62) is set as appropriate. In one embodiment example, the inside volume of the part of the pipe L21 downstream of the raw material gas buffer part L22 is set to within the range of 1/10 to ½ of the inside volume of the raw material gas buffer part L22.

It is feasible to control the amount of accumulation of the raw material gas in the raw material gas buffer part L22 (that is, the amount of feeding and supply of the raw material gas into the chamber 3) by e.g. a raw material gas accumulation amount control part based on a change in the measured value of the pressure gauge P_{L2}. More specifically, the amount of accumulation of the raw material gas can be determined and controlled based on a change in the measured value of the pressure gauge P_{L2} before and after the supply of the raw material gas into the chamber 3 and the volume of the raw material gas buffer part L22.

Various forms of open/close valves are usable as the on/off valves V2. In one embodiment example, the on/off valves V2a to V2c are provided on upstream and downstream sides of the raw material gas buffer part L22, respectively, as shown in FIG. 1. High speed on/off valves, capable of being opened and closed precisely at high speed, may be used as the on/off valves V2a to V2c. In the embodiment of FIG. 1, the on/off valve V2b has a three-way valve structure for connection with the after-mentioned inert gas addition line L5.

As explained above, the raw material gas supply line L2 is adapted to, by appropriately opening and closing the on/off valves V2 and adequately controlling the gas pressure inside the raw material gas buffer part L22 based on the change in the measured value of the pressure gauge P_{L2}, accumulate therein the raw material gas at a predetermined pressure and concentration and supply the accumulated raw material gas into the chamber 3.

Any residual raw material gas remaining in the raw material gas buffer part L22 after the supply of the raw material gas into the chamber 3 may be accumulated and used along with a raw material gas newly fed from the raw material gas supply device G2 (i.e. may be reused for supply to the chamber 3) in the next raw material gas accumulation.

After the supply of the raw material gas into the chamber 3, an inert gas may be fed into the raw material gas buffer part L22 (pipe L21) via the inert gas supply line L3 as will be explained later, so as to replace any residual gas (such as raw material gas or mixed gas of raw material gas and inert gas) remaining in the raw material gas buffer part L22 with the inert gas.

At the time when the raw material gas accumulated in the raw material gas buffer part L22 is fed and supplied into the chamber 3, the raw material gas buffer part L22 and the chamber 3 are in communication with each other. Depending on the pipe pressure loss, however, there is a possibility that it takes a long time until the pressure between the raw material gas buffer part L22 and the chamber 3 reaches an equilibrium.

In such a case, the exposure of the film formation surface 20 to the raw material gas may be continued as appropriate under a condition that the gas pressure inside the raw material gas buffer part L22 (e.g. the pressure of the mixed gas of raw material gas and carrier gas) is increased or under a condition that the pressure inside the chamber 3 is maintained by once stopping the supply of the raw material gas into the chamber 3 before reaching an equilibrium state.

Furthermore, a plurality of raw material gas supply lines L2 may be provided in parallel to the chamber 3. In the case where the vapor pressures of raw material gases in the respective raw material gas supply lines L2 are different from each other, a temperature adjusting part (such as a supply pipe temperature adjusting part having a heating mechanism such as a thermocouple, a heat exchanger, an infrared heater etc. capable of controlling the inside temperature of each pipe L21) may be provided to adjust the inside temperatures of the respective raw material gas supply lines L2. For example, in the case where two raw material gas supply lines L2 are provided to supply TMA and TDMT as raw material gases as will be explained later, the inside temperatures of these raw material gas supply lines L2 may be adjusted to 50° C. and 150° C., respectively.

The temperature adjusting part may be configured to not only adjust the temperature of the raw material gas supply line L2 but also adjust the temperature of the other constituent part such as any of those surrounded by double-dotted lines as shown in FIG. 1. Examples of such temperature adjusting part are those capable of adjusting the inside temperature of the after-mentioned inert gas addition pipe L51 (as an addition pipe temperature adjusting part) or capable of adjusting the temperature of the inner surface 30 of the chamber 3 (as an inner surface temperature adjusting part).

<Inert Gas Supply Line L3>

The inert gas supply line L3 provides a connection between the inert gas supply device G3 and the ejection port 33, and has an inert gas supply pipe L31 for supplying an inert gas fed from the inert gas supply device G3. The pipe L31 is equipped with on/off valves V3 and a mass flow controller L32. Each of the on/off valves V3 is switchable between a gas flow state (open state) and a gas cut-off state (closed state) to allow or cut off gas flow in the pipe L31. (In FIG. 1, the on/off valves V3a and V3b are disposed on a downstream side of the mass flow controller L32.) The mass flow controller L32 is configured to control the rate of gas flow in the pipe L31. As in the case of the on/off valves V1 and the like, various forms of open/close valves are usable as the on/off valves V3 without particular limitation.

The inert gas supply line L3 is adapted to supply the inert gas into the chamber 3 by appropriately opening and closing the on/off valves V3 and adequately controlling the flow rate of the inert gas from the inert gas supply device G3 by means of the mass flow controller L32 as explained above.

In the case where the device is configured to feed the inert gas from the pipe L31 to the L21 via the after-mentioned inert gas addition line L5, any temperature adjusting part may be provided to adjust the inside temperature of the pipe L31.

<Bypass Line L4>

In the raw material gas supply line L2, there may be provided a bypass line L4 on a side of the pipe L21 upstream and/or downstream of the raw material gas buffer part L22 as shown in FIG. 1. This bypass line is switchable between a communication state and a shut-off state to establish or shut off communication between the raw material gas buffer part L22 and the gas discharge system 5 by means of on/off valves V4.

In the embodiment of FIG. 1, the bypass line L4 has bypass pipes L41 each arranged to connect a portion of the pipe L21 upstream and/or downstream of the raw material gas buffer part L22 to a portion of the discharge pipe 5a of the gas discharge system 5 between the on/off valve 5b and the vacuum pump 5c. As in the case of the on/off valves V1 and the like, various forms of open/close valves are usable as the on/off valves V4 without particular limitation.

With the use of such a bypass line L4, any residual raw material gas in the raw material gas buffer part L22 can be discharged to the outside via the bypass line L4 and the gas discharge system 5 without being recycled.

<Inert Gas Addition Line L5>

There may also be provided an inert gas addition line L5 in the raw material gas supply line L2. This inert gas addition line is switchable between a communication state and a shut-off state to establish or shut off communication between the pipe L21 of the raw material gas supply line L2 and the pipe L31 of the inert gas supply line L3 by means of an on/off valve V5.

In the embodiment of FIG. 1, the inert gas addition line L5 has an inert gas addition pipe L51 arranged to connect a portion of the pipe L21 downstream of the raw material gas buffer part L22 (more specifically, the on/off valve V2b of three-way valve structure in FIG. 1) and a portion of the pipe L31 of the inert gas supply line L3 between the mass flow controller L32 and the on/off valve V3a. Further, a raw material gas buffer part pressure gauge P_{L5} is provided on the inert gas addition pipe L51 to measure a gas pressure inside the raw material gas buffer part L22. As in the case of the on/off valves V1 and the like, various forms of open/close valves are usable as the on/off valve V5 without particular limitation.

With the use of such an inert gas addition line L5, the inert gas can be fed to the raw material gas supply line L2 and used as a carrier gas to carry the raw material gas. In this case, it is feasible to determine the gas concentration of the raw material gas buffer part L22 (that is, the concentration of the raw material gas diluted with the inert gas (as the mixed gas)) according to the equation: Pa/Pox 100 by a concentration control part (not shown).

In the above equation, Pα is a measured value of the pressure gauge P_{L2} in a state that the raw material gas is fed to the evacuated raw material gas buffer part L22 and then, accumulated and sealed in the raw material gas buffer part L22; Pβ is a measured value of the pressure gauge P_{L5} in a state that only the inert gas is fed into the raw material gas buffer part L22 after the measurement of Pα.

For example, it is feasible to dilute the raw material gas with the inert gas and obtain the mixed gas of the raw material gas and the inert gas by performing a raw material gas accumulation step and a mixed gas accumulation step as follows (e.g. in advance of the after-mentioned raw material gas supply step S1 and, more specifically, at any time other than the after-mentioned stages [3], [5] and [7]).

In the raw material gas accumulation step, the raw material gas is accumulated and sealed in the raw material gas buffer part L22 of the raw material gas supply line L2 until the pressure inside the raw material gas buffer part L22 reaches a predetermined pressure.

In the subsequent mixed gas accumulation step, the inert gas is fed into the raw material gas buffer part L22 via the pipe L51 until the pressure inside the raw material gas buffer part L22 reaches a predetermined higher pressure (more specifically, a predetermined pressure higher than that in the raw material gas accumulation step). As a result, the mixed gas is obtained as desired and accumulated and sealed in the raw material gas buffer part L22.

The partial pressure of the raw material gas in the mixed gas accumulated in the raw material gas buffer part L22 in the mixed gas accumulation step is set as appropriate. In one embodiment example, the partial pressure of the raw material gas in the mixed gas is set to 1000 Pα or lower. The concentration of the raw material gas in the mixed gas is also set as appropriate. In one embodiment example, the concentration of the raw material gas in the mixed gas is set to 30% or lower as a converted value based on the partial pressure ratio of the raw material gas and the inert gas in the mixed gas. Further, the inside temperature of the pipe L51 may be adjusted to a higher temperature than the inside temperature of the pipe L21 by any temperature adjusting part (such as addition pipe temperature adjusting part).

In the case where the raw material gas accumulation step and the mixed gas accumulation step are performed again after the supply of the mixed gas into the chamber 3, an inert gas replacing step may be performed in advance (e.g. at a timing between the after-mentioned stages [5] and [6]) so as to supply only the inert gas to the pipe L21 and replace any residual gas in the pipe L21 with the inert gas. By this inert gas replacing step, the residual gas in the pipe L21 is discharged via the chamber 3 (or the bypass line 4).

<Film Forming Process Using ALD Device>

The ALD device 11 is operated to form a desired oxide film 21 on the firm formation surface 20 of the target workpiece 2 in the chamber 3 by an ALD method where a raw material gas supply step S1, a raw material gas purge step S2, an oxidant supply step S3 and an oxidant purge step S4 are sequentially performed as shown in FIG. 3.

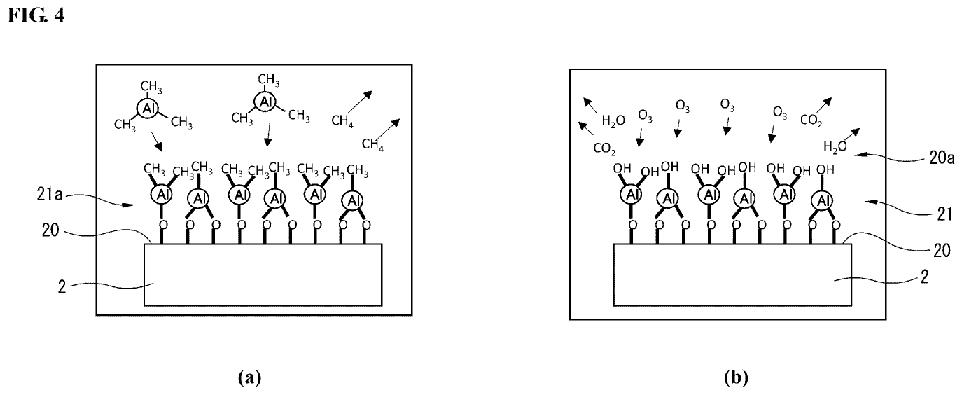

As shown in FIG. 3, the raw material gas supply step S1 is first performed. In the raw material gas supply step, the raw material gas (that is, a raw material gas containing a constituent element of the desired oxide film 21) is supplied from the raw material gas supply device G2 via the raw material gas supply line L2 and ejected into the chamber 3 from the ejection port 32. Then, the raw material gas is adsorbed onto the film formation surface 20 of the target workpiece 2 in the chamber 3 so that an adsorption layer 21a of the raw material gas is formed as shown in the reaction scheme of FIG. 4(a). In FIG. 4(a), the adsorption layer is illustrated as one molecular layer of TMA gas adsorbed on the film formation surface 20 of the substrate-shaped target workpiece 2.

In the case where e.g. an impurity substance has been adhered to the film formation surface 20 of the target workpiece 2, it is preferable to clean the film formation surface 20 (e.g. by purging away the impurity substance with the supply of the inert gas from the inert gas supply device G3 into the chamber 3 via the inert gas supply line L3) before the raw material gas supply step S1 so that the raw material gas can be easily adsorbed onto the film formation surface 20.

After the raw material gas supply step S1, the raw material gas purge step S2 is performed. In the raw material gas purge step, the inert gas is supplied from the inert gas supply device G3 via the inert gas supply line L3 and ejected into the chamber 3 from the ejection port 33 while the gas inside the chamber 3 is discharged by the suction action of the gas discharge system 5. Consequently, a residue of the raw material gas supplied in the raw material gas supply step S1 and any gas generated by adsorption of the raw material gas onto the film formation surface 20 are purged out and removed from the film formation surface 20.

The oxidant supply step S3 is subsequently performed. In the oxidant supply step, the ozone gas is supplied from the ozone gas generator G1 via the ozone gas supply line L1 and ejected into the chamber 3 from the ejection port 31. Then, the adsorption layer 21a on the film formation surface 20 is oxidized (more specifically, methyl (CH₃) of the adsorption layer is oxidized in FIG. 4(b)) by the ozone gas as shown in the reaction scheme of FIG. 4(b) whereby there is provided on the film formation surface 20 an adsorption possible region 20a for the next film forming cycle. The oxidation reaction shown in the reaction scheme of FIG. 4(b) can proceed even at room temperature (25° C.).

After that, the oxidant purge step S4 is performed as in the raw material gas purge step S2. The inert gas is supplied from the inert gas supply device G3 via the inert gas supply line L3 and ejected into the chamber 3 from the ejection port 33 while the gas inside the chamber 3 is discharged by the suction action of the gas discharge system 5. Consequently, a residue of the ozone gas supplied in the ozone gas supply step S3 and any gas generated by oxidation of the adsorption layer 21a of raw material gas are purged out and removed from the film formation surface 20.

By repeating the cycle of the above-mentioned steps S1 to S4 (hereinafter occasionally simply referred to as film forming cycle) as appropriate, the oxide film 21 is formed with a desired thickness on the film formation surface 20. Various conditions of the film forming cycle are set as appropriate depending on e.g. the desired oxide film 21.

In the case where the film forming cycle is repeated a plurality of times, the raw material gas supplied in the raw material gas supply step S1 of at least one of the film forming cycles can be of different kind from that supplied in the raw material gas supply step S1 of the other film forming cycle or cycles (when the raw material gas is supplied as the mixed gas, the mixed gases using different kinds of raw material gases can be supplied in the film forming cycles). This leads to formation of the oxide film 21 with a multilayer structure of adsorption layers 21a of the different kinds of raw material gases (i.e. the oxide film 21 in which a plurality of adsorption layers 21a are stacked).

For instance, in the case where a plurality of raw material gas supply lines L2 are provided in parallel to the chamber 3, these raw material gas supply lines L2 can be used for supply of different kinds of raw material gases so as to form the oxide film 21 of desired multilayer structure by selectively operating any of the raw material gas supply lines L2 (i.e. supplying any of the different kinds of raw material gases).

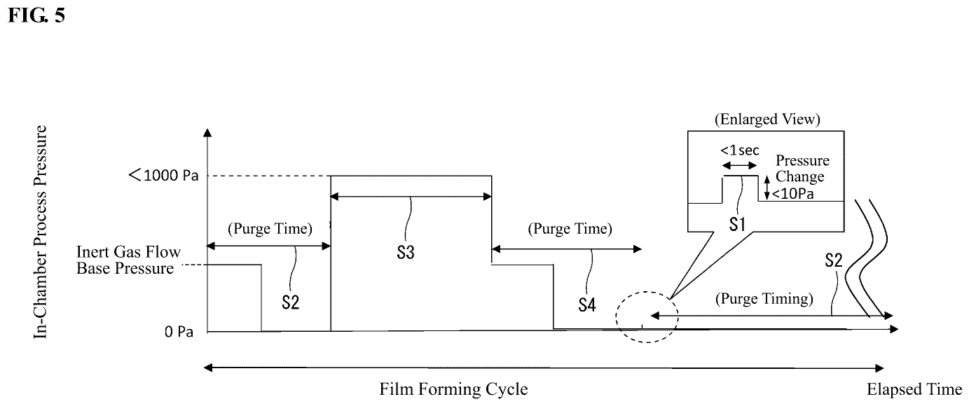

More specifically, the film forming cycle of FIG. 5 can be carried out through the following stages [1] to [8].
Stage [1]: The chamber 3 is evacuated (i.e., the gas inside the chamber 3 is sucked and discharged to the outside by the gas discharge system 5).
Stage [2]: The oxidant supply step S3 is performed (i.e., the ozone gas is supplied and sealed in the chamber 3).
Stage [3]: The oxidant purge step S4 is performed (i.e., the inert gas is supplied into the chamber 3: and then, the chamber 3 is evacuated).
Stage [4]: The chamber 3 is evacuated.
Stage [5]: The raw material gas supply step S1 is performed (i.e. the raw material gas is supplied and sealed in the chamber 3).
Stage [6]: The chamber 3 is evacuated.
Stage [7]: The raw material gas purge step S2 is performed (i.e., the inert gas is supplied into the chamber 3; and the chamber 3 is evacuated).
Stage [8]: The chamber 3 is evacuated. (This stage corresponds to the stage [1] of the next film forming cycle.)

Among the stages [1] to [8], it is preferable to perform the accumulation of the ozone gas in the ozone gas buffer part L12 at any stage other than the stage [2].

It is further preferable to perform the accumulation of the raw material gas in the raw material gas buffer part L22 at any stage other than the stage [5] among the stages

In the case where the inert gas is supplied into the raw material gas buffer part L22 of the raw material gas supply line L2 via the inert gas addition line L5 as shown in FIG. 1, it is preferable to perform the accumulation of the raw material gas in the raw material gas buffer part L22 at any stage other than the stages [3], [5] and [7]. The reason for this is that, when the inert gas is supplied into the raw material gas buffer part L22 in the stage [3] or [7], the flow rate of the inert gas could become unstable.

Each of the stages [3] and [7] may be executed once in the film forming cycle, or may be executed a plurality of times (as cycle purge) in the film forming cycle. The execution of a plurality of times of the stage [3], [7] would make it easier to suppress gas-phase mixing of the ozone gas and the raw material gas.

When the cycle purge is performed in each of the stages [3] and [7], the amount of supply of the inert gas (more specifically, the total amount of the inert gas supplied in each cycle purge) is set as appropriate. In one embodiment example, the amount of supply of the inert gas in the cycle purge is set to 10 times or more than the amount of supply of the gas into the chamber 3 during the raw material gas supply step S1 or set to 10 times or more than the amount of supply of the gas into the chamber 3 during the oxidant supply step S3.

<Inert Gas in Each of Steps S1 to S4>

In the raw material gas purge step S2 or the oxidant purge step S4, the gas flow in the chamber 3 is accelerated to shorten the time required for the removal (purging out) of the residual gas by appropriately supplying the inert gas into the chamber 3 through the inert gas supply line L3 while operating the gas discharge system 5 to suck the gas inside the chamber 3.

Depending on the inside volume and shape of the chamber 3 (particularly, in the case where the chamber has a large volume (e.g. exceeding 1 m³) or a complicated shape), there is a possibility that the flow of the raw material gas or ozone gas from the gas supply system 4 becomes low. Even in such a case, however, the gas flow can be accelerated by appropriately supplying the inert gas as mentioned above (more specifically, adjusting the amount of supply of the inert gas based on the volume and shape of the chamber 3 or intermittently supplying the inert gas).

Accordingly, it is feasible to adjust the gas flow in the chamber 3 appropriately in each of the steps S1 to S4 by supplying the inert gas as required. This makes it easy to supply a desired amount of the raw material gas or ozone gas and makes it easy to discharge the gas inside the chamber 3.

### Example of Target Workpiece 2

There is no particular limitation on the target workpiece 2 as long as a desired oxide film 21 is applicable to the film formation surface 20 of the target workpiece 2 by performing the film forming cycle as appropriate. The target workpiece 2 can be in various forms such as solid form, substrate form, powdery form (e.g. an aggregate of a plurality of particulate target workpieces 2), film form, sheet form, cloth form, fibrous form and the like.

In the oxide film forming technique using the raw material gas and the ozone gas of 80 vol % or higher, it is possible to form the oxide film at a relatively low temperature. Hence, the target workpiece, when in substrate or film form, is not limited to relatively high heat-resistant substrates such as S1 substrate. The oxide film is also applicable to substrates or films made of relatively low heat-resistant synthetic resins.

In the case where the target workpiece 2 is made of a resin material, examples of the resin material are polyester resin, aramid resin, olefin resin, polypropylene, PPS (polyphenylene sulfide), PET (polyethylene terephthalate) and the like.

As the resin material, there can also be used PE (polyethylene), PEN (polyethylene naphthalate), POM (polyoxymethylene; also called acetal resin), PEEK (polyether ether ketone), ABS resin (acrylonitrile-butadiene-styrene copolymerization synthetic resin), PA (polyamide), PFA (tetrafluoroethylene-perfluoroalkoxyethylene copolymer), PI (polyimide), PVD (polyvinyl dichloride) and the like.

The film formation surface 20 of the target workpiece 2 is not limited to a simple flat shape and can be in various shapes. As shown in FIG. 2, the target workpiece 2 may be provided in solid form with a plurality of trench grooves 22 such that the film formation surface 20 has an uneven stepped shape.

For improvement of film forming performance, the temperature of the target workpiece 2 may be adjusted as appropriate by heating or cooling with any temperature adjusting part (not shown). It is one embodiment example to adjust the temperature of the target workpiece as required such that the temperature of the film formation surface 20 during the film formation is in the range of about room temperature to 100° C.

### Example of Raw Material Gas

The raw material gas used in the raw material gas supply step S1 is a gas containing a constituent element of the oxide film (such as lithium (Li), magnesium (Mg), silicon (Si), titanium (Ti), vanadium (V), chromium (Cr), manganese (Mn), iron (Fe), cobalt (Co), nickel (Ni), copper (Cu), zinc (Zn), gallium (Ga), germanium (Ge), yttrium (Y), zirconium (Zr), molybdenum (Mo), ruthenium (Ru), rhodium (Rh), indium (In), tin (Sn), hafnium (Hf), tantalum (Ta), tungsten (W), iridium (Ir), platinum (Pt) and lead (Pb); hereinafter referred to as metal or metal element).

For example, the raw material gas can be a gas containing an organic silicon compound with a Si—O bond or Si—C bond or an organometallic compound with a metal-oxygen bond or metal-carbon bond or a gas containing an organometallic complex or a hydride of silicon or metal.

Specific examples of the raw material gas are gases of silane (that is a generic name for hydrogen silicate), TEOS (tetraethyl orthosillicate), TMS (trimethoxysilane), TES (triethoxysilane), TMA (trimethyl aluminum), TEMAZ (tetrakis(ethylmethylamino)zirconium), 3DAMAS (tris(dimethylamino)silane; SiH[N(CH₃)₂]₃), TDMAT (tetrakis(dimethylamino) titanium; Ti[N(CH₃)₂]₄), TDMAH (tetrakis(dimethylamino)hafnium; Hf[N(CH₃)₂]₄) and the like. As the raw material gas, there can also be used a gas of heterogeneous polynuclear complex containing a plurality of kinds of metal elements (as disclosed in e.g. Japanese Laid-Open Patent Publication No. 2016-210742) rather than containing one kind of metal element.

### Example of Ozone Gas

Although the ozone gas can be used at various concentrations in the oxidant supply step S3, it is preferable that the concentration of the ozone gas is as high as possible. The ozone concentration (vol %) of the high concentration ozone gas is preferably in the range of 80 to 100 vol %. The ozone gas of such high concentration can be obtained by liquefying and separating ozone from an ozone-containing gas on the basis of a difference in vapor pressure, and then, gasifying the liquefied ozone.

As the ozone gas generator G1, there can be used any of ozone generators disclosed in patent documents such as Japanese Laid-Open Patent Publication No. 2001-304756 and Japanese Laid-Open Patent Publication No. 2003-20209. These ozone generators usable as the ozone gas generator G1 are each configured to generate a high concentration ozone gas (ozone concentration≈100 vol %) by isolating ozone through liquefaction separation based on a difference in vapor pressure between ozone and another gas (e.g. oxygen). The ozone gas generator, particularly of the type having a plurality of chambers for liquefying and gasifying only ozone, enables continuous supply of the high concentration ozone gas by individual temperature control of the chambers.

For example, Pure Ozone Generator (MPOG-HM 1 A1) manufactured by Meidensha Corporation is known as one commercially available example of the high concentration ozone gas generator.

### Example of Inert Gas

The inert gas can be of any kind usable in the raw material gas purge step S2 or the oxidant purge step S4 or usable as a carrier gas to carry the raw material gas. Examples of the inert gas are N₂, Ar, He and the like.

### Example of Ejection Ports 31 to 33

The ejection ports 31 to 33 can be provided in various forms as long as the ozone gas, the raw material gas and the inert gas are respectively fed at desired feeding amounts (flow rates) and pressures into the chamber 3 from through these ejection ports.

The number of ejection ports 31, 32, 33 formed in the chamber 3 is not limited to one and may be plural. The shapes of the ejection ports 31 to 33 are set as appropriate.

For example, the ejection ports 31 to 33 can be formed in a circular shape, a rectangular shape, an oval shape, a slit shape etc.

The amounts and pressures of the respective gases fed from the ejection ports 31 to 33 are set appropriately by e.g. adequately operating the ozone gas supply line L1, the raw material gas supply line L2 and the inert gas supply line L3.

<Gas Supply Amount and Pressure>

The amounts of supply of the raw material gas, the ozone gas and the inert gas into the chamber 3 and the pressures of these respective gases (such as the pressure (partial pressure) of the ozone gas supplied into the chamber 3) are set as appropriate in view of, for example, the kind and shape of the target workpiece 2, the number of target workpieces 2 disposed in the chamber 3, the kinds and concentrations of the respective gases and the like.

For example, in the case where the film forming cycle is performed through the steps S1 to S4 as shown in FIG. 5, the supply amounts etc. of the respective gases are set appropriately such that the process pressure inside the chamber 3 during the film forming cycle falls within the range of 1000 Pα or lower. More specifically, it is one embodiment example to control the gas supply by feeding the inert gas (e.g. feeding the inert gas intermittently as will be explained later) into the chamber 3 via the inert gas supply line L3 such that the base pressure falls within the range of about 1 Pα to 1000 Pα. The time required for one film forming cycle is set as appropriate without particular limitation. In one embodiment example, the time for one film forming cycle is set to several seconds to several tens seconds (e.g. 3 seconds to 60 seconds).

At the time when the ozone gas of 80 vol % or higher is supplied in the oxidant supply step S3, it is feasible to supply the ozone gas in various manners. In one embodiment example, the supply amount etc. of the ozone gas is set as appropriate such that: the amount of exposure of the film formation surface 20 to the ozone gas is 1×10⁵ Langmuir or greater; the supply of the ozone gas accumulated in the ozone gas buffer part L12 into the chamber 3 is completed within 1 second; and the pressure inside the chamber 3 is in the range of 10 to 1000 Pα.

The above-mentioned amount of exposure to the ozone gas (1×10⁵ Langmuir or greater) is an example of ozone gas exposure amount required in the case where TMA is used as the precursor (raw material gas). In the case where the precursor is of different kind (i.e. any kind other than TMA), the required ozone gas exposure amount is varied depending on e.g. the ease of oxidation of the precursor by ozone.

In the case where the inert gas is present in the chamber 3 in addition to the ozone gas, the partial pressure of the ozone gas is set to 100 Pα or lower. Further, the pressure increase due to the supply of the ozone gas is appropriately set to 100 Pα or smaller, preferably 50 Pα or smaller, more preferably 10 Pα or smaller.

In this oxidant supply step S3, it is possible to sufficiently oxidize the adsorption layer 21a formed on the film formation surface 20 in the raw material gas supply step S1.

The amount of supply of the raw material gas into the chamber 3 in the raw material gas supply step S1 is set as appropriate, without particular limitation, so as to allow adsorption of the raw material gas onto the film formation surface 20 and to allow sufficient oxidation of the raw material gas (i.e. formation of the oxide film) in the subsequent oxidant supply step.

In one embodiment example, the supply amount etc. of the raw material gas is set as appropriate such that the amount of exposure of the film formation surface 20 to the raw material gas is 1×10⁴ Langmuir or greater. In the case where the raw material gas is supplied in the form of the mixed gas with the inert gas in the raw material gas supply step S1, it is feasible to supply the mixed gas in various manners. In one embodiment example, the supply amount etc. of the mixed gas is set as appropriate such that: the supply of the mixed gas accumulated in the raw material gas buffer part L22 into the chamber 3 is completed within 1 second; and the pressure inside the chamber 3 is in the range of 0.1 to 100 Pα.

The above-mentioned amount of exposure to the raw material gas (1×10⁴ Langmuir or greater) is an example of raw material gas exposure amount required in the case where TMA is used as the precursor and any metal material (such as Si) is deposited on the film formation surface 20. In the case where the precursor and the deposited metal material are of different kinds, the amount of adsorption of the precursor onto the film formation surface 20 would change whereby the required raw material gas exposure amount needs to be varied according to the amount of such change of the precursor adsorption amount.

The time during which the gas (i.e. the raw material gas or the mixed gas of the raw material gas and the inert gas) supplied in the raw material gas supply step S1 is kept sealed in the chamber 3 and the time during which the gas (i.e. the ozone gas) supplied in the oxidant supply step S3 is kept sealed in the chamber 3 are set as appropriate. In one embodiment example, each of these gas seal times is set to 1 to 1000 seconds. More specifically, it is one example to set the gas seal time as appropriate within the range of 1 to 1000 seconds in view of the shape (e.g. uneven stepped shape) of the film formation surface 20 of the target workpiece 2.

In each of the raw material gas purge step S2 and the oxidant purge step S4, the amount of supply of the inert gas into the chamber 3 is set appropriately such that the process pressure falls within the range of 1000 Pα or lower as mentioned above. In the case where purging is performed by the gas discharge system 5, the amount of supply of the inert gas is set to a degree that can assist in the purging. It is one example to intermittently supply the inert gas into the chamber 3 via the inert gas supply line L3 and thereby set the supply amount of the inert gas as appropriate (e.g. set the supply amount of the inert gas to be 10 times or less than the supply amount of the ozone gas) so as not to excessively dilute the raw material gas or the ozone gas in the chamber 3.

### Example of Gas Discharge System 5

There is no particular limitation on the gas discharge system 5. The gas discharge system 5 can be of any configuration as long as it is capable of maintaining the inside of the chamber 3 in a reduced pressure state such that the process pressure inside the chamber 3 falls within the range of 1000 Pα or lower as mentioned above.

Although the gas discharge system 5 is provided with the discharge pipe 5a, the on-off valve 5b and the vacuum pump 5c in the embodiment of FIG. 1, the gas discharge system 5 may additionally be provided with an ozone killer (i.e. a removal cylinder capable of decomposing ozone; not specifically shown) and the like. Further, it is preferable that the vacuum pump 5c is of the type resistant to ozone (as exemplified by a dry pump).

In the gas discharge system 5, a plurality of discharge lines may be provided and used properly in the respective steps S1 to S4. In this case, it is possible to distribute the gases discharged in the respective steps S1 to S4 over dedicated removal systems for processing of the discharged gases.

### Example of Support Part

There is no particular limitation on the support part. The support part can be of any type capable of supporting the target workpiece 2 in the chamber 3 so as not to interfere with film formation on the film formation surface 20.

### Embodiment Example 1; Adsorption of Raw Material Gas in Stage [5] by ALD Device 11

Verification was made on the pressure inside the chamber 3 and the raw material gas buffer part L22 and the adsorption amount of the raw material gas on the film formation surface 20 of the target workpiece 2 during the execution of the stage [5] after the stage [4] by the above-mentioned ALD device 11.

As the conditions for verification in this embodiment example, the volume of the chamber 3 was set to 50000 cc; and the volume of the raw material gas buffer part L22 was set to 100 cc. (The same conditions apply to the after-mentioned Embodiment Example 2.) The raw material gas accumulated in the raw material gas buffer part L22 was diluted with the inert gas fed via the inert gas supply line L3 and the inert gas addition line L4 such that the pressure of the diluted raw material gas (mixed gas) in the raw material gas buffer part L22 was 1000 Pα (the partial pressure of the raw material gas was 133 Pa). The raw material gas used was a TMA gas. The target workpiece 2 used was a S1 substrate.

With the execution of the stage [5], the pressure inside the chamber 3 and the raw material gas buffer part L22 became about 10 Pa: and the partial pressure of the raw material gas became 1.33 Pα. The adsorption amount of the raw material gas reached about 1×10⁴ Langmuir at the time when the time of exposure of the film formation surface 20 of the target workpiece 2 to the raw material gas was 1 second.

It is confirmed from the above results that, assuming the adsorption probability on the film formation surface 20 as 0.001, the exposure time required for the coverage rate (also referred to as surface coverage) to reach a saturation level of 1 is about 1 second.

### Embodiment Example 2; Adsorption of Ozone Gas in Stage [2] by ALD Device 11

Verification was made on the adsorption amount of the ozone gas on the film formation surface 20 of the target workpiece 2 during the execution of the stage [2] after the stage [1] by the above-mentioned ALD device 11.

In Embodiment Example 2, the volume of the chamber 3 was downsized to about 1/10 of the volume of the chamber 3 in Embodiment Example 1. The reason for such downsizing was to, since only one target workpiece 2 was disposed in the chamber 3 in Embodiment Example 2, make it easy to eject the ozone gas to the film formation surface 20 and make it possible to sufficiently suppress adhesion of the ozone gas to the inner wall surface of the chamber 3. It has thus been shown that, when the position of ejection of the ozone gas to the film formation surface 20 is properly set, there is suppressed the influence of gas reduction due to adhesion of the gas to the chamber wall surface so that the volume of the chamber 3 can be downsized.

As the conditions for verification in this embodiment example, the ozone concentration of the ozone gas accumulated in the ozone gas buffer part L12 was set to 80 to 100 vol %; and the target workpiece 2 used was a S1 substrate.

With the execution of the stage [2], the adsorption amount of the ozone gas reached about 3×10⁵ Langmuir at the time when the pressure inside the chamber 3 and the raw material gas buffer part L22 was 40 Pa; and the time of exposure of the film formation surface 20 of the target workpiece 2 to the ozone gas was 1 second.

It is confirmed from the above result that, even in the case where a plurality of target workpieces 2 is disposed in the chamber 3, it is possible to form oxide films 21 on respective film formation surfaces 20 of the target workpieces in one operation.

### Embodiment Example 3; Film Formation by ALD Device 11

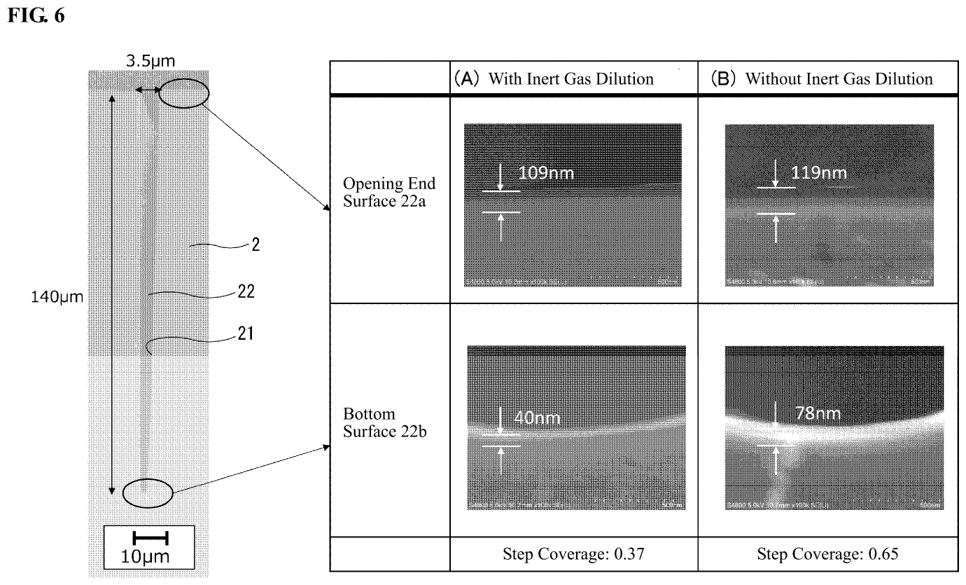

An oxide film 21 was formed on the target workpiece 21 by performing the film forming cycle (i.e. executing the stages [1] to [8] as appropriate) with the use of the above-mentioned ALD device 11, and then, cross sections of the oxide film on opening end surface 22a and bottom surfaces 22b of trench grooves 22 of the target workpiece were observed for thickness evaluation (nm) of the oxide film. The observation results are shown in FIG. 6.

Herein, the column (A) of FIG. 6 shows the observation results in the case where the ozone gas was diluted with the inert gas (Ar) in the stage [2]; whereas the column (B) of FIG. 6 shows the observation results in the case that the ozone gas was not diluted in the stage [2] (that is, the ozone gas concentration was 80 to 100 vol %).

The raw material gas used was a TMA gas; and the target workpiece 2 used was a S1 substrate having formed therein the trench grooves 22 with a depth of 140 μm and an opening width of 3.5 μm.

As shown in the column (B) of FIG. 6, the thickness of the oxide film 21 formed on the opening end surface 22a was 119 nm; and the thickness of the oxide film 21 formed on the bottom surface 22b was 78 nm. The oxide film 21 shown in the column (B) had a relatively large thickness and a relatively high aspect ratio (as determined by dividing the thickness of the oxide film 21 on the bottom surface 22b by the thickness of the oxide film 21 on the opening end surface 22a) in comparison to those of the oxide film 21 shown in the column (A).

It has been confirmed from the above results that the higher the ozone gas concentration, the greater the number of ozone molecules reaching the depth of the trench groove 22, whereby it becomes possible to sufficiently promote the formation of the oxide film 21 on the bottom surface 22b of the trench groove 22. It view of the fact that the ozone gas of high concentration (80 to 100 vol %) obtained through liquefaction contains less impurities such as heavy metals, it has also been confirmed that the use of such a high-concentration ozone gas leads to not only a reduction of impurities in the oxide film 21 but also an expected improvement in coverage property of the oxide film 21 on the trench groove 22.

### Embodiment Example 4; Configuration Example of Pipes L11, L21 and L31

In the above-mentioned ALD device 11, the pipes L11, L21 and L31 can be provided in various forms as long as they are capable of supplying the respective gases into the chamber 3.

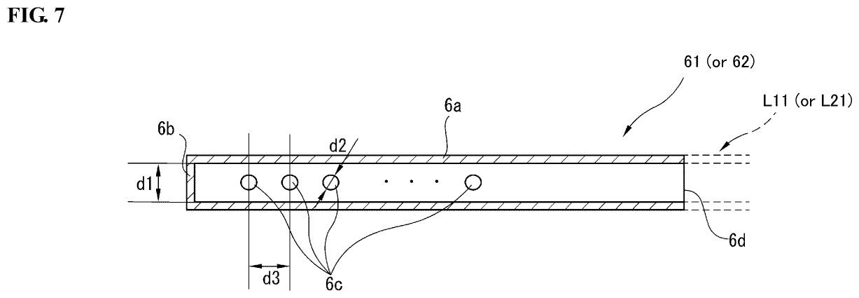

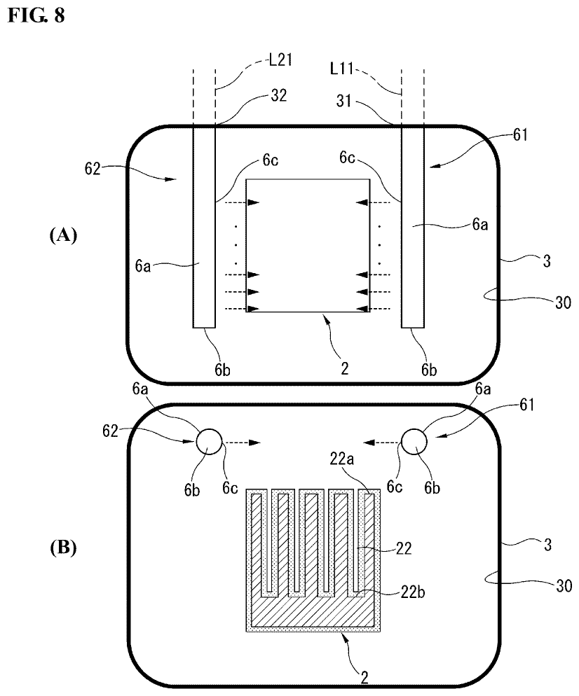

For instance, a downstream end part (chamber 3-side end part) of the pipe L11, L21 may be configured to pass through the ejection port 31, 32 in the inside-outside direction of the chamber 3 and protrude in the chamber 3, rather than to be connectable to the ejection port 31, 32 as shown in FIG. 1. It is one example of such pipe configuration that the downstream end parts of the pipes L11 and L12 have nozzle structures formed with an ozone gas nozzle portion 61 and a raw material gas nozzle portion 62, respectively, as shown in FIGS. 7 and 8.

As shown in FIGS. 7 and 8, each of the gas nozzle portions 61 and 62 includes: a circular cylindrical section 6a extending protrudingly from the inner surface 30 of the chamber 3 at a position of the ejection port 31, 32; a lid section 6b closing one end of the cylindrical section 6a in an axial direction of the cylindrical section; and a plurality of nozzle holes 6c opening through an outer cylindrical surface of the cylindrical section 6a in a radial direction of the cylindrical section 6a. In the illustrated example, the nozzle holes 6c are provided at predetermined intervals (e.g. intervals d3 as will be explained later) in the axial direction of the cylindrical section 6a.

In the example of FIG. 8, the gas nozzle portions 61 and 62 are arranged to protrude from the inner surface 30 in parallel with each other within the chamber 3 such that the nozzle holes 6c of the gas nozzle portion 61 and the nozzle holes 6c of the gas nozzle portion 62 are opposed to and face each other.

There is no particular limitation on the materials and shapes of the gas nozzle portions 61 and 62. The materials and shapes of the gas nozzle portions 61 and 62 are selected as appropriate depending on the kinds and amounts of the respective gases supplied into the chamber 3. For instance, the gas nozzle portion 61, 62 can be each formed by selecting any suitable material from stainless steel (SUS) materials, quartz materials, ceramic materials and the like and processing the selected material into a desired shape. In one embodiment example, the gas nozzle portion is shaped such that: the inner diameter d1 of the cylindrical section 6a is in the range of 2 to 10 mm; the hole diameter d2 of the nozzle holes 6c is in the range of 1 to 5 mm; and the interval d3 between the adjacent nozzle holes 6c is 5 mm or greater.

Further, the gas nozzle portion 61, 62 may be formed integral with the downstream end part of the pipe L11, L21 or may be formed as a separate piece detachable (e.g. detachable at an opening end part 6d thereof in FIG. 8) from the downstream end part of the pipe L11, L21.

It is feasible to dispose the target workpiece 2 at any position inside the chamber 3. In one embodiment example, the target workpiece 2 is positioned perpendicularly to a space between the gas nozzle portions 61 and 62 (hereinafter occasionally simply referred to as nozzle 61-to-nozzle 62 space) such that the opening end surface 22a of the target workpiece 2 is opposed to and faces the nozzle 61-to-nozzle 62 space as shown in FIG. 8.

With the use of the pipes L11 and L12 each equipped with the nozzle structure of Embodiment Example 4, the respective gases are supplied into the chamber 3 via the pipes L11 and L12 by being ejected from through the nozzle holes 6c of the gas nozzle portions 61 and 62 (e.g. as indicated by dotted arrows in FIG. 8). This facilitates diffusion of the respective gases (hereinafter occasionally simply referred to as gas diffusion) in the chamber 3.

In the case where the nozzle holes 6c of the gas nozzle portion 61 and the nozzle holes 6c of the gas nozzle portion 62 are opposed to each other as shown in FIG. 8, the ozone gas and the raw material gas (or the mixed gas of the raw material gas and the inert gas) (hereinafter occasionally simply referred to as the gases) are ejected so as to collide with each other. This makes it possible to diffuse the gases while suppressing adhesion of the gases to the inner surface 30 (i.e. diffuse the gases before causing adhesion of the gases), that is, makes it possible to achieve effective gas diffusion.

In Embodiment Example 4, the film forming cycle was performed in the same manner as in Embodiment Example 3. As a result, there was confirmed the formation of an oxide film 21 similar to that shown in FIG. 6.

### Embodiment Example 5; Configuration Example for Heating Respective Gases in Chamber 3

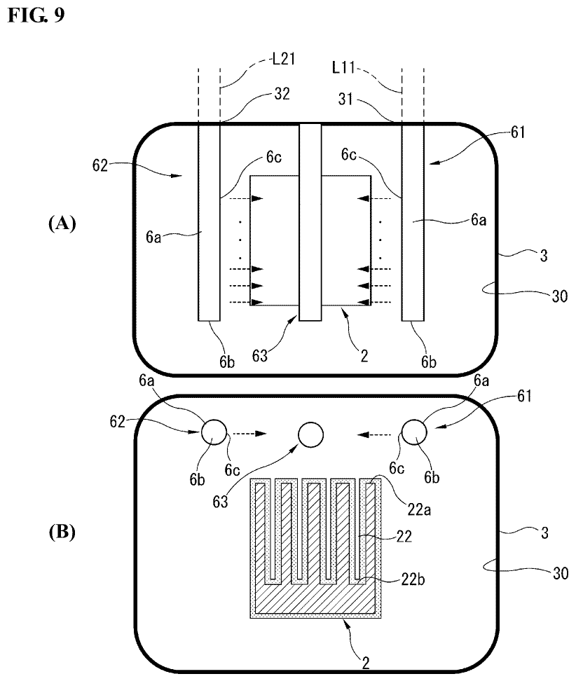

FIG. 9 schematically shows a configuration for heating the respective gases in the chamber 3 in Embodiment Example 5. In this configuration, a heating part (as a chamber inside heating part) 63 is provided between the nozzle portions 61 and 62.

As shown in FIG. 9, the heating part 63 has a cylindrical column-shaped heating body supported to extend from the inner surface 30 of the chamber 3 at a position between the ejection ports 31 and 32.

The heating part 63 can be provided in various forms as long as it is capable of heating the gases between the nozzle portions 61 and 62. Preferably, the heating part 53 is configured to heat the gases between the nozzle portions 61 and 62 to a higher temperature than the inside temperatures of the pipes L11 and L21.

The heating configuration of Embodiment Example 5 allows collision of the gases ejected from the nozzle holes 6c of the gas nozzle portions 61 and 62 while causing heating and interference of the gases between the nozzle portions 61 and 62 by the heating part 63. It is thus possible to suppress excessive physical adsorption of the raw material gas (or the mixed gas of the raw material gas and the inert gas) as compared to Embodiment Example 4. It is further possible to suppress reliquefaction of the gases during the gas diffusion because the gases are heated between the nozzle portions 61 and 62.

In Embodiment Example 5, the film forming cycle was also performed in the same manner as in Embodiment Example 3 with the use of the above-configured ALD device 11. As a result, there was confirmed the formation of an oxide film 21 similar to that shown in FIG. 6.

### Embodiment Example 6; Another Configuration Example for Heating Respective Gases in Chamber 3

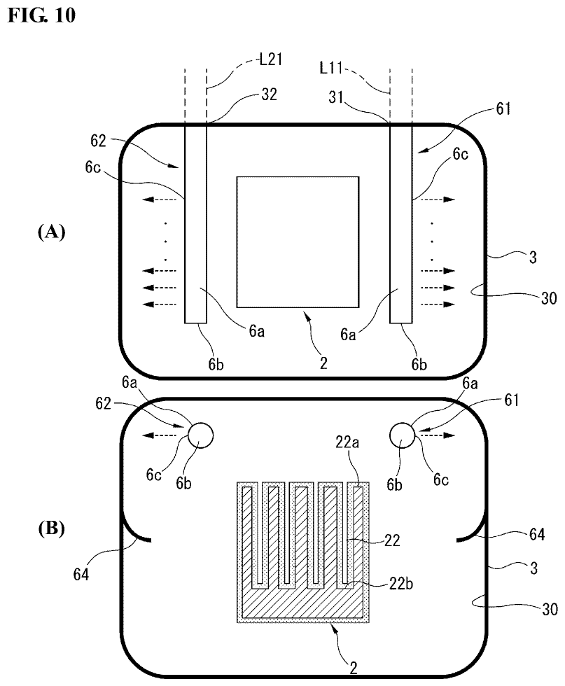

FIG. 10 schematically shows another configuration for heating the respective gases in the chamber 3 in Embodiment Example 6. In this configuration, the gas nozzle portions 61 and 62 are arranged to protrude from the inner surface 30 of the chamber in parallel with each other such that the nozzle holes 61c of the gas nozzle portion 61 and the nozzle holes 61c of the gas nozzle portion 62 are oriented in opposite directions and facing away from each other as shown in FIG. 10.

In the example of FIG. 10, a temperature adjusting part (as an inner surface temperature adjusting part) is provided to adjust the temperature of the inner surface 30 of the chamber 3. Although the temperature of the inner surface 30 can be adjusted as appropriate, the temperature adjusting part is preferably configured to adjust the temperature of the inner surface 30 to at least a higher temperature than the inside temperatures of the ozone gas supply pipe and the raw material gas supply pipe.

Further, gas flow guide portions 64 are formed on the inner surface 30 in a shape protruding from the inner surface 30 so as to guide the respective gases flowing along the inner surface 30 toward the position of the target workpiece 2 in the chamber 3.

The gas flow guide portions 64 can be provided in various forms as long as they are capable of guiding the respective gases in the chamber 3 as mentioned above. The shape of the gas flow guide portions 64 and the number of gas flow guide portions 64 provided in the chamber 3 are set as appropriate. In the example of FIG. 10, the gas flow guide portions 64 are arranged at positions displaced from the ejection direction of the nozzle holes 6c (e.g. displaced toward the lower side in FIG. 10 from the ejection direction indicated by dotted arrows) relative to the inner surface 30 and are each shaped to extend in a curve toward the position of the target workpiece 2 in the chamber 3.

The heating configuration of Embodiment Example 6 allows heating of the gases ejected from the nozzle holes 6c of the gas nozzle portions 61 and 62 even without arranging the heating part 63 in the chamber 3 as in Embodiment Example 5, and makes it possible to suppress reliquefaction of the gases during the gas diffusion as in Embodiment Example 5. This configuration contributes to simplification and downsizing of the chamber 3 because of no need to provide the heating part 63 such as that of Embodiment Example 5. Furthermore, the arrangement of the gas flow guide portions 64 on the inner surface 30 enables sufficient gas diffusion in the chamber 3 as desired.

In Embodiment Example 6, the film forming cycle was also performed in the same manner as in Embodiment Example 3 with the use of the above-configured ALD device 11. As a result, there was confirmed the formation of an oxide film 21 similar to that shown in FIG. 6.

Although the ALD device and ALD method according to the present invention has been described above by way of the specific embodiments, the ALD device and ALD method according to the present invention is not limited to those of the above-described specific embodiments. Various modifications and variations of the above-described embodiments are possible within the range that does not impair the features of the present invention. All such modifications and variations are included in the technical scope of the present invention.

1-31. (canceled)

32. An atomic layer deposition method for forming an oxide film on a film formation surface of a target workpiece in a chamber of an atomic layer deposition device, the atomic layer deposition method comprising:
a raw material gas supply step of supplying a raw material gas, which contains a constituent element of the oxide film, into the chamber, thereby forming an adsorption layer of the raw material gas on the film formation surface;
a raw material gas purge step of removing, from the film formation surface, a residue of the raw material gas supplied in the raw material gas supply step and a gas generated by adsorption of the raw material gas onto the film formation surface;
an oxidant supply step of supplying an ozone gas of 80 vol % or higher into the chamber, thereby oxidizing the adsorption layer formed on the film formation surface; and
an oxidant purge step of removing, from the film formation surface, a residue of the ozone gas supplied in the oxidant supply step and a gas generated by oxidation of the adsorption layer,
wherein a temperature of the film formation surface during the formation of the oxide film is set to 100° C. or lower,
wherein the atomic layer deposition device comprises:
the chamber in which the target workpiece is removably disposed;
a gas supply system that supplies the respective gases into the chamber; and
a gas discharge system that discharges any gas inside the chamber by suction to the outside of the chamber and maintains the inside of the chamber in a reduced pressure state,
wherein the gas supply system comprises: a raw material gas supply line having a raw material gas supply pipe for supplying a raw material gas into the chamber; an ozone gas supply line having an ozone gas supply pipe for supplying an ozone gas of 80 vol % or higher into the chamber; and an inert gas supply line having an inert gas supply pipe for supplying the inert gas into the chamber, and
wherein the ozone gas supply line comprises: an ozone gas buffer part that freely accumulates and seals therein the ozone gas flowing in the ozone gas supply pipe and freely feeds the accumulated ozone gas into the chamber by opening and closing of an open/close valve mounted on the ozone gas supply pipe; and an ozone gas buffer part pressure gauge that measures a gas pressure inside the ozone gas buffer part.

33. The atomic layer deposition method according to claim 32,
wherein, in the raw material gas supply step, the raw material gas is supplied as a mixed gas with the inert gas,
wherein the raw material gas supply line comprises: an inert gas addition line having an inert gas addition pipe switchable between a communication state and a shut-off state to establish or shut off communication between the raw material gas supply pipe and the inert gas supply pipe; a raw material gas buffer part that freely accumulates and seals therein the raw material gas flowing in the raw material gas supply pipe and the inert gas flowing from the inert gas supply pipe into the raw material gas supply pipe via the inert gas addition line and freely feed the accumulated raw material gas and inert gas into the chamber by opening and closing of an open/close valve mounted on the raw material gas supply pipe; and a raw material gas buffer part pressure gauge that measures a gas pressure inside the raw material gas buffer part, and
wherein the mixed gas supplied in the raw material gas supply step is prepared in advance by execution of: a raw material gas accumulation step of accumulating the raw material gas in the raw material gas buffer part until a pressure inside the raw material gas buffer part reaches a predetermined pressure; and then, a mixed gas accumulation step of obtaining and accumulating the mixed gas in the raw material gas buffer part by feeding the inert gas into the raw material gas buffer part via the inert gas addition pipe until the pressure inside the raw material gas buffer part reaches a predetermined pressure higher than that in the raw material gas accumulation step.

34. The atomic layer deposition method according to claim 33, wherein, in the raw material gas accumulation step, a partial pressure of the raw material gas in the mixed gas accumulated in the raw material gas buffer part is 1000 Pα or lower, and a concentration of the raw material gas in the mixed gas is 30% or lower as a converted value based on a partial pressure ratio of the raw material gas and the inert gas in the mixed gas.

35. The atomic layer deposition method according to claim 32, wherein the raw material gas supply line comprises: a raw material gas buffer part that freely accumulates and seals therein the raw material gas flowing in the raw material gas supply pipe and freely feeds the accumulated raw material gas into the chamber by opening and closing of an open/close valve mounted on the raw material gas supply pipe; and a raw material gas buffer part pressure gauge that measures a gas pressure inside the raw material gas buffer part.

36. The atomic layer deposition method according to claim 32, wherein the raw material gas supply line comprises an inert gas addition line having an inert gas addition pipe switchable between a communication state and a shut-off state to establish or shut off communication between the raw material gas supply pipe and the inert gas supply pipe.

37. The atomic layer deposition method according to claim 33, wherein the atomic layer deposition device comprises a raw material gas accumulation amount control part that controls an amount of accumulation of the raw material gas in the raw material gas buffer part based on a change in measured value of the raw material gas buffer part pressure gauge.

38. The atomic layer deposition method according to claim 33, wherein a volume inside the raw material gas buffer part is larger than or equal to 1/500 of a volume inside the chamber.

39. The atomic layer deposition method according to claim 33, wherein a volume inside a part of the raw material gas supply pipe downstream of the raw material gas buffer part is in a range of 1/10 to ½ of a volume inside the raw material gas buffer part.

40. The atomic layer deposition method according to claim 33, wherein the raw material gas supply line comprises a bypass line provided on a side of the raw material gas supply pipe upstream and/or downstream of the raw material gas buffer part and having a bypass pipe switchable between a communication state and a shut-off state to establish or shut off communication between the raw material gas buffer part and the gas discharge system.

41. The atomic layer deposition method according to claim 33, wherein the atomic layer deposition device comprises an addition pipe temperature adjusting part that adjusts a temperature inside the inert gas addition pipe to a higher temperature than a temperature inside the raw material gas supply pipe.

42. The atomic layer deposition method according to claim 32,
wherein the gas supplied into the chamber in the raw material gas supply step is kept sealed in the chamber for a predetermined time, and then, is discharged to the outside of the chamber in the raw material gas purge step, and
wherein the gas supplied into the chamber in the oxidant supply step is kept sealed in the chamber for a predetermined time, and then, is discharged to the outside of the chamber in the oxidant purge step.

43. The atomic layer deposition method according to claim 32, wherein the atomic layer deposition device comprises an ozone gas accumulation amount control part that controls an amount of accumulation of the ozone gas in the ozone gas buffer part based on a change in measured value of the ozone gas buffer part pressure gauge.

44. The atomic layer deposition method according to claim 32, wherein a volume inside the ozone gas buffer part is larger than or equal to 1/50 of a volume inside the chamber.

45. The atomic layer deposition method according to claim 32, wherein a volume inside a part of the ozone gas supply pipe downstream of the ozone gas buffer part is in a range of 1/10 to ½ of a volume inside the ozone gas buffer part.

46. The atomic layer deposition method according to claim 32,
wherein the ozone gas supply pipe has an ozone gas nozzle portion formed on a downstream end part thereof and arranged to protrude from an inner surface of the chamber,
wherein the raw material gas supply pipe has a raw material gas nozzle portion formed on a downstream end part thereof and arranged to protrude from the inner surface of the chamber, and
wherein each of the ozone gas nozzle portion and the raw material gas nozzle portion includes: a cylindrical section protruding from the inner surface of the chamber; a lid section closing a front end of the cylindrical section in a protruding direction of the cylindrical section; and a plurality of nozzle holes opening through a cylindrical surface of the cylindrical section in a radial direction of the cylindrical section.

47. The atomic layer deposition method according to claim 46,
wherein the ozone gas nozzle portion and the raw material gas nozzle portion protrude from the inner surface of the chamber in parallel with each other, and
wherein the nozzle holes of the ozone gas nozzle portion and the nozzle holes of the raw material gas nozzle portion are positioned opposed to and facing each other.

48. The atomic layer deposition method according to claim 47,
wherein the atomic layer deposition device comprises a chamber inside heating part arranged in a space between the ozone gas nozzle portion and the raw material gas nozzle portion within the chamber to heat the space between the ozone gas nozzle portion and the raw material gas nozzle portion within the chamber,
wherein the chamber inside heating part is configured to heat the space between the ozone gas nozzle portion and the raw material gas nozzle portion to a higher temperature than a temperature inside the ozone gas supply pipe and a temperature inside the raw material gas supply pipe.

49. The atomic layer deposition method according to claim 46,
wherein the atomic layer deposition device comprises an inner surface temperature adjusting part that adjusts a temperature of the inner surface of the chamber,
wherein the inner surface temperature adjusting part is configured to adjust the temperature of the inner surface of the chamber to a higher temperature than a temperature inside the ozone gas supply pipe and a temperature inside the raw material gas supply pipe,
wherein the ozone gas nozzle portion and the raw material gas nozzle portion protrude from the inner surface of the chamber in parallel with each other, and
wherein the nozzle holes of the ozone gas nozzle portion and the nozzle holes of the raw material gas nozzle portion are oriented in opposite directions and facing away from each other.

50. The atomic layer deposition method according to claim 49, wherein the chamber has a gas flow guide portion provided protrudingly from the inner surface of the chamber such that the gas flow guide portion extends from the inner surface of the chamber toward a position of the target workpiece in the chamber.
